(19) United States
(12) Patent Application Publication
(10) Pub. No.: US 2025/0372392 A1
(43) Pub. Date: Dec. 4, 2025

(54) DRY-ETCHING METHOD FOR SILICON OXIDE LAYER

(71) Applicant: Samsung Electronics Co., Ltd., Suwon-si (KR)

(72) Inventors: Heejeong Kim, Suwon-si (KR); Akiou Kikuchi, Tokyo (JP); Kunihiro Yamauchi, Tokyo (JP); Buseo Choi, Suwon-si (KR); Hayoung Jeon, Suwon-si (KR); Hwiseok Jun, Suwon-si (KR); Wonwoong Chung, Suwon-si (KR); Younjoung Cho, Suwon-si (KR)

(73) Assignees: SAMSUNG ELECTRONICS CO., LTD., Suwon-si (KR); CENTRAL GLASS COMPANY, LIMITED, Yamaguchi (JP)

(21) Appl. No.: 19/217,162

(22) Filed: May 23, 2025

(30) Foreign Application Priority Data
May 28, 2024 (KR) 10-2024-0069640

(51) Int. Cl. H01L 21/311

(52) U.S. Cl. CPC H01L 21/31116

(57) ABSTRACT

Provided is a method for dry-etching a silicon oxide layer, the method includes selectively etching a first layer including the silicon oxide layer by allowing etching gas including hydrogen fluoride, an amine compound, and inert gas to react with a stack structure including the first layer and a second layer, which includes a material different from the silicon oxide layer and is stacked on the first layer, in which the first layer includes the silicon oxide layer, the selectively-etching includes allowing the etching gas to self-limiting react with the exposed region at the first layer and removing the region subject to the self-limiting reaction.

### CROSS-REFERENCE TO RELATED APPLICATION

This application claims priority under 35 U.S.C. § 119 to Korean Patent Application No. 10-2024-0069640 filed on May 28, 2024, in the Korean Intellectual Property Office, the disclosure of which is incorporated by reference herein in its entirety.

### FIELD

Embodiments of the present disclosure described herein relate to a method for dry-etching a silicon oxide layer, and more particularly, relate to a method for selectively dry-etching a silicon oxide layer in a stack structure.

### BACKGROUND

When a fine layer is formed in the fabricating process of a semiconductor device, a process requiring the precise control of an etch amount while selectively etching a silicon oxide layer (SiO₂) has been increasingly required.

However, when an existing wet-etching approach is employed to etch the silicon oxide layer, the control of the etch amount is difficult despite a higher etch selectivity. In addition, according to the wet-etching approach, an isotropic etching process is performed, such that the realization of the fine layer is difficult. A plasma-etching approach may be employed as a different approach to etch the silicon oxide layer. According to the plasma etching-approach, although the fine layer is realized, a desired thin film may not be selectively removed due to a lower etch selectivity. In addition, according to the plasma etching approach, a lower layer may be damaged by plasma.

In relation to such an issue, dry-etching the silicon oxide layer without plasma would be advantageous.

### SUMMARY

Embodiments of the present disclosure provide a method for dry-etching a silicon oxide layer, capable of selectively etching a fine silicon oxide pattern.

According to an embodiment, a method for dry-etching a silicon oxide layer includes selectively etching a first layer including the silicon oxide layer by allowing etching gas including hydrogen fluoride, an amine compound, and inert gas to react with a stack structure including the first layer and a second layer including a material different from the silicon oxide layer, and stacked on the first layer, the first layer includes the silicon oxide layer, the selectively-etching of the first layer includes allowing the etching gas to self-limiting react with an exposed region at the first layer (i.e., self-limiting reaction), and removing the region subject to the self-limiting reaction, wherein the amine compound includes at least one of compound of Chemical Formula 1,

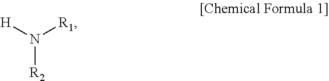

wherein each of R₁ and R₂ is independently hydrogen or a substituted or unsubstituted aliphatic or aromatic hydrocarbon group having 1 to 12 carbon atoms, wherein the substituted hydrocarbon group is substituted with nitrogen, oxygen, sulfur, phosphorus, and/or halogen atoms.

According to an embodiment of the present disclosure, a method for dry-etching a silicon oxide layer includes a dry-etching step for removing the silicon oxide layer by allowing etching gas including hydrogen fluoride, an amine compound of Chemical Formula 1, and inert gas to react with the silicon oxide layer, and the dry-etching step includes allowing the etching gas to self-limiting react with an exposed region of the silicon oxide layer, and removing a region subject to the self-limiting reaction.

According to an embodiment of the present disclosure, a method for fabricating a semiconductor device includes selectively dry-etching a silicon oxide layer by allowing etching gas including hydrogen fluoride, an amine compound of Chemical Formula 1, and inert gas to react with a semiconductor substrate having a stack structure in which silicon oxide layers and silicon nitride layers are alternately stacked on each other in a first direction, and the selectively dry-etching of the silicon oxide layer includes allowing the etching gas to self-limiting react with an exposed region of the silicon oxide layer, and removing the region subject to the self-limiting reaction.

### BRIEF DESCRIPTION OF THE FIGURES

The above and other objects and features of the present disclosure will become apparent by describing in detail embodiments thereof with reference to the accompanying drawings.

FIG. 1 is a flowchart illustrating a method for dry-etching a silicon oxide layer according to an embodiment of the present disclosure.

FIG. 2 is a graph schematically illustrating an adsorptivity of amine compounds including ammonia, a primary amine compound, a secondary amine compound, and a tertiary amine compound onto the surface of a silicon oxide layer, and the reactivity between hydrogen fluoride and the silicon oxide layer.

FIGS. 3A to 3D illustrate cross-sectional views illustrating stack structures including a silicon oxide layer to be etched in a dry-etching method for the silicon oxide layer according to an embodiment of the present disclosure.

FIG. 4 is a view schematically illustrating an etching device according to an embodiment of the present disclosure.

FIG. 5 is a flowchart illustrating an example method for dry-etching a silicon oxide layer by using the etching device of FIG. 4.

FIG. 6 is a graph illustrating etch rate of a silicon oxide layer over time when a stage temperature is 35° C., and when the internal pressure of a reactor is 3 torr.

FIGS. 7A to 7C are graphs illustrating etch amounts of etching targets depending on the temperature, and illustrate the selectivity of a specific etching target.

FIG. 8 is a graph illustrating an etch amount of an etching target as a function of a temperature, when hydrogen fluoride is employed as etching gas.

FIG. 9 is a cross-sectional view illustrating the stack structure employed in Experimental Example B-1.

FIG. 10 is a graph illustrating an etch amount of each amine compound in Experimental Example B-1.

FIG. 11 is an SEM image illustrating the cross-section of a stack structure after the etching process is performed in Experimental Example B-2.

FIG. 12 is a cross-sectional view illustrating a stack structure employed in Experimental Example B-3.

FIG. 13 is an SEM image illustrating an etch amount of the stack structure when the etching process is performed using dimethylamine and trimethylamine in Experimental Example B-3 and when the stack structure is viewed in a cross-sectional view.

FIGS. 14A and 14B are graphs illustrating the etch behavior as a function of pressure when the thickness of a silicon oxide layer is 10 nm.

FIG. 15 illustrates SEM images of cross-sections of etching results of table 7 depending on reaction times and amine compounds.

### DETAILED DESCRIPTION

Hereinafter, embodiments of the present disclosure will be described in more detail with reference to accompanying drawings, for the more detailed description of the present disclosure. However, the present disclosure can be embodied in a different form without limitation to embodiments described herein.

Unless specified otherwise, all “numbers” for expressing an amount of an ingredient or a reaction condition used in this specification and claims should be interpreted as being modified by the term “about” in all cases. Therefore, unless specified contrarily, a numeric parameter described in the present disclosure and claims is an approximate value varied depending on desired characteristics to be obtained through the subject matter of the present disclosure. As employed in this specification, the term “about” is intended to contain the variation of ±20% of the specific amount in some embodiments, the variation of ±10% of the specific amount in some embodiments, the variation of ±5% of the specific amount in some embodiments, the variation of ±1% of the specific amount in some embodiments, the variation of ±0.5% of a specific amount in some embodiments, when specifying a value of a mass, a weight, time, a volume, a concentration, a percentage, or an amount, when the variation is proper to perform the disclosed method.

In addition, the unit employed in this specification is based on “weight” unless specified otherwise. For example, unit of “%” or “ratio” refers to “weight % (wt %)” or “weight ratio (wt ratio)”. The “weight %” refers to “weight %” in which any one ingredient is occupied in the whole composition, unless specified otherwise.

In addition, the numerical range used herein includes all possible combinations of lower and upper limits and all values within the range of the lower and upper limits, an increment logically derived from the form and width of the defined range, all double-limited values, and upper and lower limits of the numerical range limited to different forms. Values outside a defined numerical range, which are likely to occur due to experimental errors or through rounding of values unless otherwise defined in the specification of the present disclosure are also included in the defined numerical range.

In this specification, the term “comprise” is an open-type expression (comprise) having the equivalent meaning to the expression of “include”, “contain”, “have”, or “characterized by”, and an element, a material, or a process, which is not listed additionally, is not excluded. However, the expression of “comprises” may be any one of a closed-type (consist of) or a partially-closed type (consist essentially of) expression.

An embodiment of the present disclosure relates to a method for selectively etching a silicon oxide layer in the fabricating process of a semiconductor through a dry-etching process. In more detail, an embodiment of the present disclosure relates to a method for selectively removing only a silicon oxide layer in a stack structure in which a silicon oxide layer and a different material are stacked. An embodiment of the present disclosure provides a method for selectively removing a silicon oxide layer effectively without performing a heat treatment process to remove a reaction product not used in an etching reaction, when the silicon oxide layer is selectively removed. An embodiment of the present disclosure provides a method for selectively removing a silicon oxide layer without plasma, when the method includes a gas phase etching approach for removing a thin film through a chemical reaction after injecting etching gas into a reactor (chamber).

Hereinafter, embodiments of the present disclosure will be described in more detail with respect to accompanying drawings.

FIG. 1 is a flowchart illustrating a method for dry-etching a silicon oxide layer according to an embodiment of the present disclosure.

Referring to FIG. 1, according to an embodiment of the present disclosure, the method for dry-etching the silicon oxide layer includes allowing etching gas to react with the silicon oxide layer (S110) and removing the silicon oxide layer (S120). The allowing of the etching gas to react with the silicon oxide layer is allowing the etching gas to react in a self-limiting manner (i.e., self-limiting reaction) with an exposed region of the silicon oxide layer. A reaction product from the self-limiting reaction is subsequently removed from the surface of the silicon oxide layer. The self-limiting reaction and the removing of the reaction product may be repeated N times ('N′ is an integer equal to or greater than ‘0’).

An etching process for the silicon oxide layer may be performed inside a reactor of an etching device. The details of the etching device will be described later.

According to an embodiment of the present disclosure, the allowing of the etching gas to self-limiting react with the exposed region of the silicon oxide layer is performed by placing a target substrate including the silicon oxide layer inside the reactor, and supplying the etching gas at a specific flow rate for a specific time. The temperature for the reaction between the silicon oxide layer and the etching gas may be set in a specific range.

The etching gas reacts with the exposed region of the silicon oxide layer. For example, the etching gas reacts with the silicon oxide layer exposed to the outside. As the reaction between the etching gas and the silicon oxide layer proceeds, the surface the silicon oxide layer, where it is exposed to the outside, is covered with the product from the reaction between the etching gas and the silicon oxide layer. When the reaction product fully covers the exposed surface of the silicon oxide layer, the speed of the reaction between the etching gas and the silicon oxide layer is reduced. The reaction product may be removed through a purge process. According to an embodiment of the present disclosure, the silicon oxide layer may be provided in a structure in which a layer in type different from a type of the silicon oxide layer is stacked on a top surface of the silicon oxide layer, and the exposed region of the silicon oxide layer may be a lateral surface instead of the top surface of the silicon oxide layer.

According to an embodiment of the present disclosure, the sequence including allowing the etching gas to self-limiting react with the exposed region of the silicon oxide layer, and then removing the reaction product from the region reacting in a self-limiting manner may be repeated multiple times. For example, the sequence may be repeated in various cycles such as two cycles, five cycles, or ten cycles.

In the sequence, the number of cycles may be determined based on the thickness of a silicon oxide layer to be etched, a material of a different insulating layer alternately stacked, and the thickness of the different insulating layer. While the etching process is repeated multiple times, the etching process may be repeated under the same condition or under mutually different conditions. For example, the reaction temperature or the flow rate of the etching gas in the first cycle may differ from the reaction temperature or the flow rate of the etching gas in a different cycle.

According to an embodiment of the present disclosure, the etching gas may include hydrogen fluoride, amine compound, and inert gas.

The amine compound may contain at least one compound of Chemical Formula 1

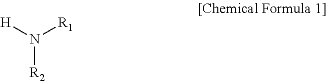

In Chemical Formula 1, each of R₁ and R₂ is independently hydrogen or a substituted or unsubstituted aliphatic or aromatic hydrocarbon group having 1 to 12 carbon atoms. The substituted hydrocarbon group can be a hydrocarbon group substituted with nitrogen, oxygen, sulfur, phosphorus, and/or halogen atoms. In some embodiments, R₁ and R₂ can be directly bound to each other to be provided in a cyclic form.

According to an embodiment of the present disclosure, the amine compound is a primary amine and/or a secondary amine, and a tertiary amine is not contained in the amine compound, e.g., the compound is devoid of a tertiary amine.

In the present disclosure, the etching reaction of the silicon oxide layer is a reaction showing an atomic layer etching (ALE) behavior. In some embodiments, the amine compound is adsorbed to the exposed region of the silicon oxide layer. In some embodiments, the adsorption of the amine compound continuously proceeds until the amine compound substantially covers an entire portion of the exposed region, that is, until the adsorption of the amine compound to the exposed region of the silicon oxide layer is saturated. After the amine compound is adsorbed to the surface of the silicon oxide layer, the amine compound may react with hydrogen fluoride and the silicon oxide layer. The reaction product of a fluorosilicate amine salt may be produced through the reaction between the silicon oxide layer, the hydrogen fluoride, and the amine compound. In some embodiments, the reaction product is produced while being vaporized. Accordingly, the reaction product may be easily removed from the target substrate, so residues do not remain on the target substrate.

The amine compound has various adsorption ratios and chemical reactivity on the surface of the silicon oxide layer, depending on the type and the size of a functional group covalently bonded to nitrogen.

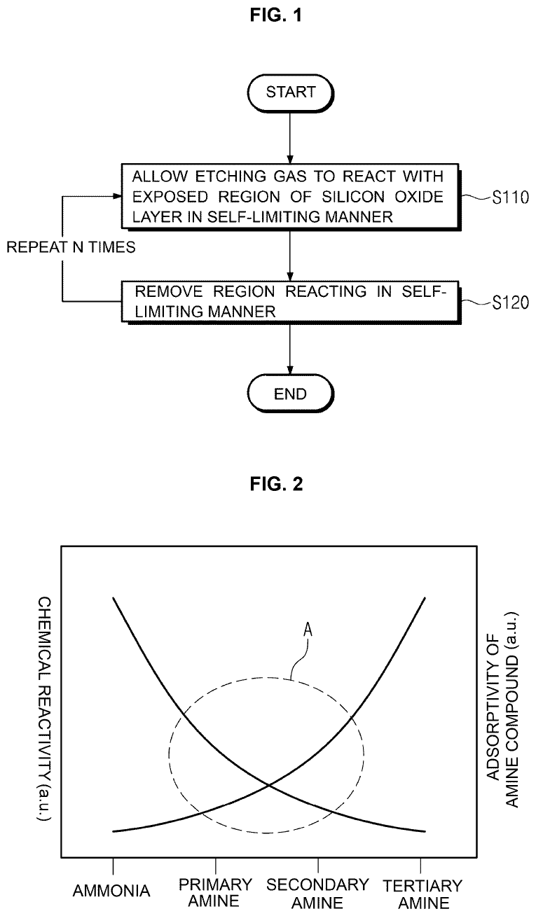

FIG. 2 is a graph schematically illustrating the adsorption ratio of a nitrogen-containing compound including ammonia, a primary amine compound, a secondary amine compound, and a tertiary amine compound onto the surface of the silicon oxide layer, and the reactivity between the hydrogen fluoride and the silicon oxide layer.

Referring to FIG. 2, the ammonia, the primary amine compound, the secondary amine compound, and the tertiary amine compound are sequentially increased in the adsorption ratios onto the surface of the silicon oxide layer, but sequentially decreased in the chemical reactivity with the hydrogen fluoride and the silicon oxide layer. Such a tendency of the absorption ratio and the reactivity of the nitrogen-containing compounds may depend on the molecular size. In other words, ammonia, the primary amine compound, the secondary amine compound, and the tertiary amine compound are sequentially increased in molecular size, and thus sequentially increased in the adsorption due to van der waals attractive force. However, ammonia, the primary amine compound, the secondary amine compound, and the tertiary amine compound are sequentially lowered in the possibility of reaction with a different molecule (hydrogen fluoride and/or silicon oxide) due to the molecular size.

The etching reaction onto the surface of the silicon oxide layer needs to increase the adsorption of the amine compound while maintaining the chemical reaction speed such that the chemical reaction speed is not lowered. In the present disclosure, a region in which the adsorption of the amine compound is ensured and the chemical reaction speed is not lowered, is indicated as region A in the graph.

According to an embodiment of the present disclosure, the tertiary amine compound is not employed, because the tertiary amine compound shows a lower chemical reaction speed, due to the difficult adsorption onto the silicon oxide layer. Ammonia reacts with hydrogen fluoride and silicon oxide to produce a by-product such as ammonium fluorosilicate. Accordingly, in some embodiments, ammonia remains even after etching, so ammonia is not employed.

According to an embodiment of the present disclosure, the amine compound may include, without limitation, methylamine, dimethylamine, methyl-ethylamine, ethylamine, diethylamine, propylamine, dipropylamine, butylamine, dibutylamine, tertiary butylamine, di-tert butylamine, pyrrolidine, piperidine, piperazine, pyridine, or pyrazine. In some embodiments, one or more hydrogens of the amine compound may be substituted with a different atom, for example, halogen.

The primary amine compound may include methylamine, ethylamine, propylamine, butylamine, or tertiary butylamine.

The secondary amine compound may include dimethylamine, diethylamine, di-n-propylamine, diisopropylamine, dibutylamine, or di-tert-butylamine.

In some embodiments, the inert gas may be employed as carrier gas, and may be selected from stable gas which does not react with hydrogen fluoride or an amine compound. The inert gas may be N₂, He, Ne, Ar, Kr and/or Xe. According to an embodiment of the present disclosure, the inert gas may be Ar or N₂, and may be, especially, Ar. The inert gas may be included in the etching gas or may not be included in the etching gas. The proportion of the inert gas included in the etching gas is a value obtained by dividing the number of moles of the inert gas by the number of moles of hydrogen fluoride, and may range from 0 to 100. For example, the proportion of the inert gas may be 10 or less, or 5 or less., e.g., 5, 4, 3, 2, 1 or less.

According to an embodiment of the present disclosure, although the etching gas includes hydrogen fluoride, an amine compound, and inert gas, the etching gas may include a material, such as a hydrogen fluoride salt of the amine compound, produced through the reaction between hydrogen fluoride and the amine compound.

According to an embodiment of the present disclosure, the etching reaction among hydrogen fluoride, an amine compound, and silicon oxide may be performed under a specific condition to show the ALE behavior. For example, at least one of the reaction temperature for the etching reaction, the time for the etching reaction, or a ratio in flow rate between components constituting the etching gas may have a value in a specific range.

According to an embodiment of the present disclosure, the temperature for the reaction between the silicon oxide layer and the etching gas may be remarkably lower than the temperature for the reaction when ammonia is employed as the etching gas. For example, the temperature for the reaction between the silicon oxide layer and the etching gas may range from −50° C. to 100° C. According to an embodiment of the present disclosure, the temperature for the reaction between the silicon oxide layer and the etching gas may range from −30° C. to 80° C., −30° C. to 50° C., −30° C. to 40° C. or −30° C. to 35° C.

The time (for example, the time for exposing the etching gas to the silicon oxide layer) for the etching reaction may range about 10 seconds to about 300 seconds, e.g., 10, 25, 50, 75, 100, 125, 150, 175, 200, 225, 250, 275, or 300 seconds. Since the etching reaction is made at the lower temperature, the time for the etching reaction may range from, for example, 100 seconds to 200 seconds such that the amine compound is sufficiently adsorbed. In some embodiments, the time for the etching reaction may be time for the etching reaction in each cycle or the sum of times for the etching reaction in all cycles, when the etching process is repeated multiple times.

In some embodiments, one cycle may include a first step for allowing the etching gas to self-limiting react with the exposed region of the silicon oxide layer for the time ranging from 10 seconds to 35 seconds, and a second step for purging remaining etching gas after reaction with the reaction product for the time ranging from 0.5 second to one minute. According to an embodiment, the first step may be performed for the time ranging from 10 seconds to 23 seconds, from 15 seconds to 25 seconds, or from 17 seconds to 23 seconds. The second step may be performed for the time from one second to 60 seconds, from one second to 30 seconds, or from one second to 15 seconds.

According to an embodiment of the present disclosure, a proportion in flow rate of the amine compound may range from 1% to 70%, for example, from 5% to 60%, or 10% to 50%, based on the whole etching gas. In addition, the relative ratio in flow rate between the hydrogen fluoride and the amine compound included in the etching gas may range from 0.05:1 to 1:50, or may range from 0.01 to 1:30 hydrogen fluoride: amine compound.

According to an embodiment of the present disclosure, the pressure of the etching gas may range from 0.001 torr to 10 torr, or any range therein. The partial pressure between the amine compound and hydrogen fluoride may range from 0.001 torr to less than 10 torr, or any range therein.

According to an embodiment of the present disclosure, hydrogen fluoride and the amine compound may be mixed before being supplied into the reactor, and hydrogen fluoride and the amine compound in a mixed status may be supplied into the reactor. However, an embodiment of the present disclosure is not limited thereto. For example, each of hydrogen fluoride and the amine compound may be individually supplied into the reactor. For example, hydrogen fluoride and the amine compound may be sequentially supplied into the reactor. When hydrogen fluoride and the amine compound are sequentially supplied into the reactor, the sequence for supplying hydrogen fluoride and the amine compound may be changed. When hydrogen fluoride and the amine compound are supplied in the mixed status to the reactor, hydrogen fluoride and the amine compound react with each other to produce fluorosilicate salt of amine. Fluorosilicate salt of amine may be supplied in a gas phase to the reactor.

According to an embodiment of the present disclosure, the etching process for the silicon oxide layer using the etching gas may be applied to various forms of silicon oxide layers. For example, the etching gas may be applied to a silicon oxide layer in a stack structure in which the silicon oxide layer is interposed between different materials. In particular, when the silicon oxide layer and a material different from the silicon oxide layer, such as a silicon nitride layer, are stacked in a vertical direction, the silicon oxide layer may be etched in a horizontal direction. When the silicon oxide layer is present in the form of a single layer within the stack structure, a reaction surface etched may correspond to a lateral surface of the layer. In addition, the etching gas may be applied to the etching of the silicon oxide layer within a stack structure in which the silicon oxide layer and a different material are alternately stacked. The stack structure according to the present disclosure may be distinguished from a structure having an exposed top surface and a flat-panel form, in that a surface portion exposed by the etching gas is present only on a lateral surface in the stack structure according to the present disclosure.

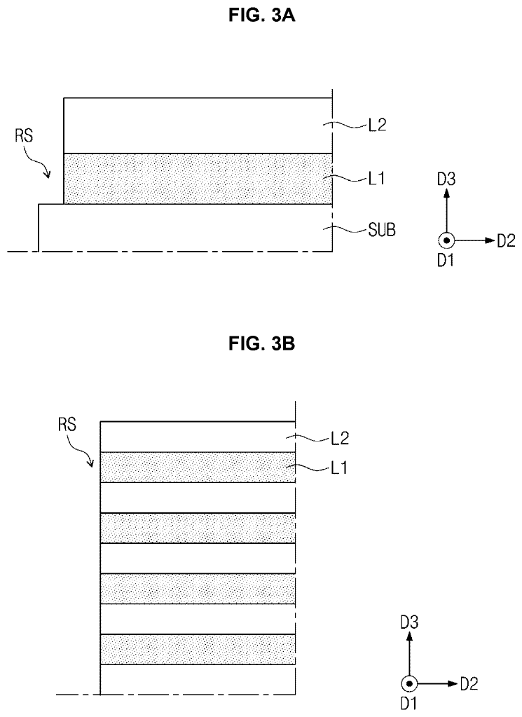

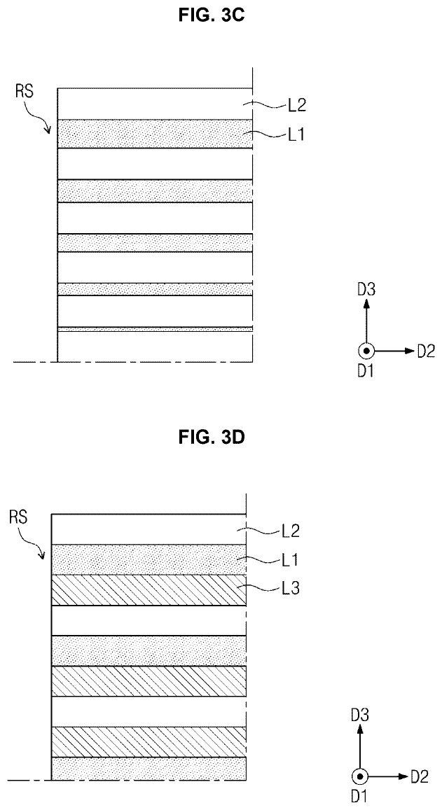

FIGS. 3A to 3D illustrate cross-sectional views illustrating stack structures including a silicon oxide layer to be etched in the method for dry-etching the silicon oxide layer according to an embodiment of the present disclosure.

Referring to FIG. 3A, the stack structure may include a first layer L1 and a second layer L2 sequentially stacked on a substrate SUB and including mutually different materials. The first layer L1 may be a silicon oxide layer, and the second L2 may be a layer including a different material, instead of the silicon oxide layer. For example, the second layer L2 may include a different insulating material, instead of the silicon oxide layer. According to an embodiment of the present disclosure, the second layer L2 may be a layer including at least one of a silicon nitride layer, silicon (for example, polysilicon), or SiOCN. For example, the second layer L2 may be the silicon nitride layer. However, the material included in the second layer L2 is not limited thereto. For example, the material included in the second layer L2 may be selected from among materials having a selectivity different from a selectivity of the silicon oxide layer with respect to the etching gas according to the present disclosure.

The substrate SUB for disposing the silicon oxide layer thereon may be provided in various forms. For example, the substrate SUB may be a silicon wafer, a metal substrate, or a glass substrate.

The first layer L1 may be provided on a top surface of the substrate SUB, and the second layer L2 may be provided on a top surface of the first layer L1. The first layer L1 and the second layer L2 may be provided on a plane defined by a first direction D1 and a second direction D2 crossing each other. For example, each of the first layer L1 and the second layer L2 may be provided in a direction (hereinafter, a horizontal direction) of extending the plane defined by the first direction D1 and the second direction D2. FIG. 3A, which illustrates a cross-sectional view of the first layer L1 and the second layer L2 taken in one direction, illustrates that the first layer L1 and the second layer L2 extend in the second direction D2.

According to an embodiment of the present disclosure, when the etching gas is supplied into the stack structure, an exposed lateral surface of the first layer L1 becomes a reaction region RS. A top surface and a bottom surface of the first layer L1 make contact with the substrate SUB and the second layer L2, to be prevented from being exposed to the outside. Accordingly, the top surface and the bottom surface of the first layer L1 may be prevented from reacting with the etching gas. When the reaction is made in the reaction region RS, the first layer L1 is etched in the second direction D2. The second layer L2 may not be etched due to the selective reaction of the etching gas, or may remain in an original state due to the selective reaction of the etching gas, due to a significantly-smaller etch amount even if the second layer L2 is etched, after the etching process is finished.

Referring to FIG. 3B, the stack structure may include first layers L1 and second layers L2 including mutually different materials, and the first layers L1 and the second layers L2 may be alternately stacked on each other. The first layers L1 and the second layers L2 may be provided on the plane defined by the first direction D1 and the second direction D2 crossing each other.

The first layers L1 and the second layers L2 may be alternately stacked on each other in a direction, that is, a third direction D3, normal to the plane defined by the first direction D1 and the second direction D2. The number of times of stacking the first layers L1 and the second layers L2 may be modified variously depending on the structure to be formed. For example, the stack structure may be variously modified from the simplest form in which one first layer L1 is interposed between two second layers L2 to a form in which first layers L1 are provided among at least two second layers L2, for example, ten second layers L2.

As illustrated in FIGS. 3B and 3C, the first layers L1 and the second layers L2 may be provided to have various thicknesses. For example, all the first layers L1 and the second layers L2 may have an equal thickness. Alternatively, all the first layers L1 may have an equal thickness and all the second layers L2 may have an equal thickness, but the thickness of the first layers L1 may be different from the thickness of the second layers L2. Alternatively, the thicknesses of the first layers L1 and the second layers L2 may be varied depending on positions. As described above, the thicknesses of the first layers L1 and the second layers L2 may be set to various values depending on a structure to be formed.

Referring to FIG. 3D, the stack structure may include at least three layers including mutually different materials. For example, the stack structure may include the first layer L1, the second layer L2, and a third layer L3, and one (for example, the first layer L1) of the first layer L1, the second layer L2, and the third layer L3 may include a silicon oxide layer. Two remaining layers (the second layer L2 and the third layer L3) from among the first layer L1, the second layer L2, and the third layer L3 may include mutually different materials. According to an embodiment of the present disclosure, each of the second layer L2, and the third layer L3 may individually include at least one of a silicon nitride layer, polysilicon, or SiOCN. However, an insulating material included in the second layer L2 and the third layer L3 is not limited thereto.

The sequence of stacking the first layer L1, the second layer L2, and the third layer L3 may be variously modified. For example, when the first layer L1 and the second layer L2 are sequentially stacked on each other, the third layer L3 may be provided on at least one of the first layer L1 or the second layer L2.

The etching process for the silicon oxide layer according to an embodiment of the present disclosure is performed inside the reactor of the etching device. Accordingly, hereinafter, the etching device to perform the etching process for the silicon oxide layer will be described.

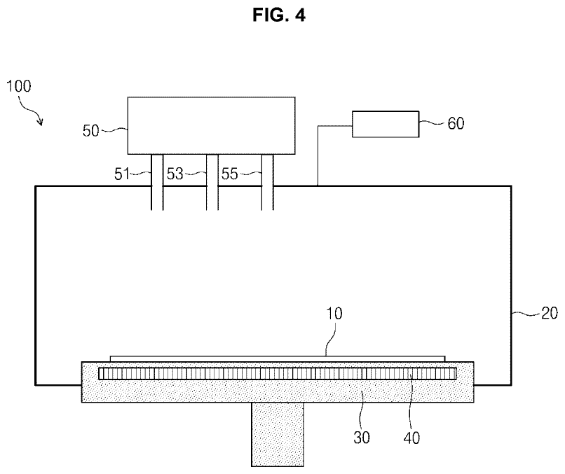

FIG. 4 is a view schematically illustrating an etching device according to an embodiment of the present disclosure.

Referring to FIG. 4, an etching device 100 may include a reactor 20 to receive a target substrate 10, a gas supply 50 to supply gas to the reactor 20, and a controller 60 to control an internal temperature (for example, the temperature of a stage 30) of the reactor 20, or internal pressure of the reactor 20.

The reactor 20, which provides a space to receive the target substrate 10 such that the target substrate 10 is etched, may include a stage 30 provided inside the reactor 20 to support the target substrate 10.

The gas supply 50 supplies the etching gas to the reactor 20. The gas supply 50 may include a first gas supply unit 51 to supply hydrogen fluoride into the reactor 50, a second gas supply unit 53 to supply an amine compound, and a third gas supply unit 55 to supply inert gas. Each of the first to third gas supply units 51, 53, and 55 may be individually connected to the reactor 20 to supply hydrogen fluoride, the amine compound, and/or inert gas, to the reactor 20. However, the type of gas supplied into the reactor 20, and the connection relationship between the first to third gas supply units 51, 53, and 55 and the reactor 20 are not limited thereto. For example, one gas supply unit or two gas supply units may be provided. For example, inert gas may be provided to the reactor 20, or may not be provided to the reactor 20. In this case, the third gas supply unit 55 for the inert gas may be connected to the reactor 20 or omitted from the reactor 20. In addition, at least a portion of the etching gas may be first mixed before being supplied into the reactor 20, and may be provided to the reactor 20 through one or two gas supply units. For example, fluorosilicate salt of the amine compound may be provided to the reactor 20 through one gas supply unit, instead of individually supplying each of hydrogen fluoride and the amine compound.

A gas discharge line (not illustrated) may be provided in the reactor 20 to discharge internal gas from the reactor 20. The gas discharge line may be connected to a vacuum pump to purge the gas out of the reactor 20.

The controller 60 may include a vacuum exhaust unit (not illustrated) to control the internal pressure of the reactor 20, an additional device such as a heating unit 40 to heat the stage 30, and a control circuit to control the additional device. In this case, the heating unit 40 may be provided inside the stage 30 or at a position adjacent to the stage 30 to heat the target substrate 10. For example, the heating unit 40 may be provided inside the stage 30 to set the temperature of the target substrate 10 to a temperature proper to perform the etching process. In addition, the heating unit 40 may be provided on a wall of the reactor 20 to control the internal temperature of the reactor 20.

According to an embodiment of the present disclosure, the controller 60 may maintain the internal temperature of the reactor 20 in the range of −50° C. to 150° C. when performing the etching process. For example, the controller 60 may maintain the internal temperature of the reactor 20 to range from −50° C. to 100° C., or from −50° C. to 30° C., or any range therein. According to an embodiment of the present disclosure, the controller 60 may maintain the internal pressure of the reactor 20 to range from 0.001 torr to 10 torr, or any range therein. In addition, the partial pressure of the amine compound and hydrogen fluoride may range from 0.001 torr to less than 10 torr, or any range therein.

The control circuit may be provided, for example, in the form of a computer, which includes program, a memory, or a central processing unit (CPU). The program is embedded therein with a step group to perform a series of operations, and to control a substrate temperature, the opening/closing of each value of the gas supply unit 50, the flow rate of each gas, or the internal pressure of the reactor 20, depending on program.

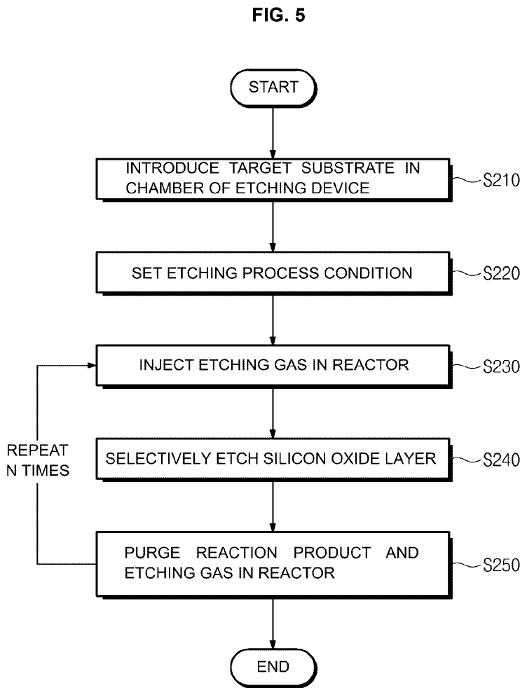

FIG. 5 is a flowchart illustrating the method for dry-etching the silicon oxide layer by using the etching device of FIG. 4.

Referring to FIG. 5, according to an embodiment of the present disclosure, the method for dry-etching the silicon oxide layer may be performed in the sequence of introducing the target substrate into the reactor of the etching device (S210), setting an etching condition when the etching process is performed (S220), injecting the etching gas into the reactor depending on the etching condition (S230), selectively etching the silicon oxide layer (S240), and purging the reaction product in the reactor and the etching gas inside the reactor (S250).

The target substrate refers to a substrate having the silicon oxide layer which is formed on the substrate to be etched. The target substrate may be a semiconductor substrate used when fabricating the semiconductor device.

In some embodiments, when the target substrate is disposed on the stage in the reactor, the internal temperature and the internal pressure of the reactor may be controlled.

Thereafter, the etching gas may be supplied into the reactor. The flow rate of the etching gas supplied into the reactor may be controlled by the controller. Although the etching gas may be supplied at a partially different flow rate ratio depending on the shape or the thickness of the silicon oxide layer to be etched, the etching gas may be supplied in a specific range allowing the etching reaction to show the ALE behavior.

According to an embodiment of the present disclosure, the proportion in the flow rate of the amine compound may range from 1% to 70%, for example, range from 5% to 60%, or range 10% to 50%, based on the whole etching gas supplied into the reactor. In addition, the relative ratio in flow rate between the hydrogen fluoride and the amine compound included in the etching gas may range from 0.05:1 to 1:50 hydrogen fluoride: amine compound, or may range from 0.01 to 1:30 hydrogen fluoride: amine compound.

According to an embodiment of the present disclosure, the pressure of the etching gas may range from 0.001 torr to 10 torr, or any range therein. The partial pressure between the amine compound and hydrogen fluoride may range from 0.001 torr to less than 10 torr, or any range therein.

When the ratio in flow rate between hydrogen fluoride and the amine compound is out of the range, the effect of the self-limiting is not exhibited when the amine compound is adsorbed. Without being bound by theory, in the relative ratio in flow rate between the hydrogen fluoride and the amine compound included in the etching gas, when hydrogen fluoride exceeding the relative ratio is supplied, the silicon oxide layer and a layer with a different material adjacent to the silicone layer may be etched together, so it is difficult to ensure the etch selectivity between the silicon oxide layer and the adjacent layer including a different material. When the amine compound exceeding the relative ratio is supplied, an etch rate may be excessively reduced, after the amine compound is adsorbed onto the surface of the silicon oxide layer.

According to an embodiment of the present disclosure, the selectively-etching of the silicon oxide layer includes allowing the etching gas to self-limiting react with the exposed region of the silicon oxide layer, and then removing the region subject to the self-limiting reaction. The region subject to the self-limiting reaction reacts with the reaction product and then remaining etching gas is purged and removed. According to an embodiment of the present disclosure, the sequence may be repeated at multiple cycles.

The self-limiting reaction is started, as the etching gas is adsorbed onto the exposed surface of the silicon oxide layer. In particular, the amine compound may be adsorbed onto the surface of the silicon oxide layer and then may react with the silicon oxide layer and the hydrogen fluoride. The reaction product may be produced while being vaporized, and purged together with the remaining etching gas. In this case, the self-limiting reaction may be performed for the time ranging from 10 seconds to 30 seconds, and the etching gas remaining after reacting with the reaction product may be removed by purging for the time ranging from 0.5 seconds to 1 minute.

The sequence of selectively removing the silicon oxide layer through the self-limiting reaction by injecting the etching gas into the reactor and of purging the remaining reaction product and the remaining etching gas may be repeated N times (N is an integer equal to or greater than ‘0’, e.g., 0, 1, 2, 3, 4, 5, 6, 7, 8, 9, 10, 11, 12, 13, 14, 15, 16, 17, 18, 19, 20) depending on the thickness of the silicon oxide layer to be etched. According to an embodiment, the sequence may be repeated at least one time.

According to an embodiment of the present disclosure, the reaction among the silicon oxide layer, hydrogen fluoride, and the amine compound shows an atomic layer etching (ALE) behavior. The reaction may be actually started as the amine compound is adsorbed to the exposed surface of the silicon oxide layer. Whether the reaction is performed may be determined depending on the shape or the area of the exposed region of the silicon oxide layer. However, according to an embodiment of the present disclosure, the lateral surface of the silicon oxide layer is exposed to the outside, instead of an entire top surface of the silicon oxide layer. The area of the lateral surface of the silicon oxide layer is significantly smaller than the area of the top surface of the silicon oxide layer. Accordingly, when the whole amine compound is adsorbed and saturated onto the lateral surface of the silicon oxide layer, the etch rate of the silicon oxide layer is reduced. In this case, the adsorption speed and the reaction speed with the silicon oxide layer may be varied depending on the type of the amine compound which is adsorbed. In addition, since the etching reaction shows the ALE behavior, the silicon oxide layer may be etched in units of an atomic layer N times. Accordingly, the silicon oxide layer may be significantly easily etched at a desired degree (for example, at a specific depth). According to an embodiment of the present disclosure, the etch amount of the silicon oxide layer may be precisely controlled.

According to an embodiment of the present disclosure, in a method for dry-etching the silicon oxide layer, as hydrogen fluoride and the amine compound are used as the etching gas, the etching by-product is reduced while the silicon oxide layer is etched at a higher selectivity over a different material (for example, the silicon nitride layer). Accordingly, since the silicon oxide layer has the higher etch selectivity over the different material (for example, the silicon nitride layer), the silicon oxide layer may not be etched simultaneously with the different material (for example, the silicon nitride layer).

In addition, in some embodiments, since the silicon oxide layer is etched at a higher etch rate as compared as a process of employing hydrogen fluoride and ammonia as etching gas, the target substrate need not be heated to increase the reaction speed. In addition, the product (that is, ammonium fluorosilicate) resulting from the reaction between the hydrogen fluoride and the ammonia, which is produced in the process of employing the hydrogen fluoride and ammonia as the etching gas, is not made as a by-product, thereby preventing the defect resulting from the by-product. In particular, in some embodiments, a process (for example, a post-heating process) of post-treating the target substrate to remove the by-product resulting from the reaction between ammonia and hydrogen fluoride may be omitted. In the post-treating process, the target substrate may be exposed to a higher temperature. In some embodiments, the target substrate may be exposed to the higher temperature, the etch amount of the silicon oxide layer may be changed and the etch selectivity over the different material may be reduced, which may be resolved by omitting the post-treating process.

According to an embodiment of the present disclosure, in the method for etching the silicon oxide layer by supplying the etching gas to the silicon oxide layer using the etching device, the higher selectivity is shown over the layer including a different material, such as the silicon nitride layer, adjacent to the silicon oxide layer. The method for dry-etching the silicon oxide layer according to the disclosure may be applied to the fine structure including the silicon oxide layer having the thickness or the line width of 10 nm or less.

According to an embodiment of the present disclosure, as amine compounds in the second order or less (that is, the primary amine compound and/or the secondary amine compound) are employed, the silicon oxide layer may be selectively etched, at a lower temperature and under higher pressure, as compared to when the tertiary amine compound is employed. Most of all, according to an embodiment of the present disclosure, as the etching gas including the amine compounds in the second order or less is employed, the silicon oxide layer may be etched selectively from different materials (for example, polysilicon, the silicon nitride layer, or SiOCN).

According to an embodiment of the present disclosure, as amine compounds (that is, the primary amine compound and/or the secondary amine compound) in the second order or less are employed, the silicon oxide layer may be selectively etched, at a lower temperature and higher pressure, as compared to when the tertiary amine compound is employed.

The method for selectively etching the stack structure of the silicon oxide layer described above may be employed in the fabricating process of various semiconductor devices.

For example, in a fabricating process of a NAND flash memory device, an oxide layer grown in an isolation layer is etched before forming an oxide-nitride-oxide (ONO) insulating layer and a control gate layer on a floating gate. In this case, when the etch amount of the oxide layer is not precisely controlled, the floating gate layer has different exposure degrees in each device region. Accordingly, the characteristics of the devices may become irregular. In addition, when the oxide layer is not selectively removed, even the floating gate electrode exposed during the etching may be etched. In the method for dry-etching the silicon oxide layer in the stack structure according to an embodiment of the present disclosure, when the silicon oxide layer is etched, the higher etch selectivity and the etching efficiency may be achieved together. In addition, the method for selectively etching the stack structure of the silicon oxide layer may be applied to a process of removing a mold oxide layer after forming a cylinder-type lower electrode of a capacitor or a process of selectively removing the silicon oxide layer by employing the silicon nitride layer as an etching barrier when forming an air gap for the insulation between inter-metal wires, in the fabricating process of a memory device.

The above-described fabricating process of the semiconductor device is provided only for illustrative purposes. The method for selectively etching the stack structure of the silicon oxide layer may be applied to various fabricating processes of a semiconductor device within the concept of the present disclosure.

Although embodiments of the present disclosure have been described, those skilled in the art will understand that various modifications, and variations are possible, without departing from the scope and spirit of the present disclosure as disclosed in the accompanying claims. Accordingly, the technical scope of the present disclosure is not limited to the detailed description of this specification, but should be defined by the claims.

### EXPERIMENTAL EXAMPLE A. ETCHING BEHAVIOR FOR FLAT SUBSTRATE

### Experimental Example A-1: Etching Behavior for Silicon Oxide Layer Depending on Type and Time of Etching Gas Over Time

After preparing a flat substrate having a silicon oxide layer, which is formed on a top surface thereof, etch rates for the silicon oxide layer were compared with each other by variously changing the types of nitrogen-containing compounds. In more detail, etching gas including nitrogen-containing compounds, hydrogen fluoride, and inert gas was employed. Ammonia, secondary amine, and tertiary amine were employed as the nitrogen-containing compounds. Dimethylamine (DMA) was employed as the secondary amine, and trimethylamine (TMA) was employed as the tertiary amine.

The etching degree of the silicon oxide layer based on the etching gas was measured depending on the temperature and time on the flat substrate.

The evaluation condition is shown as in Table 1. In Table 1, time corresponds to time taken to repeat a 10-second purge process five times after performing the etching reaction for 20 seconds or to perform a purge process for 60 seconds, after performing the etching reaction for 100 seconds. The following temperature indicates a stage temperature, and the temperature on a sidewall was maintained to 80° C.

TABLE 1

| | | Hydrogen | Inert |
|---|---|---|---|
| | NH₃/TMA/DMA | fluoride (HF) | gas (Ar) |
| Flow rate (sccm) | 40 | 40 | 35 |
| Time (sec) | 100 | 100 | 100 |
| Pressure (Torr) | 3.0 | 3.0 | 3.0 |
| Temperature (° C.) | 35/60/120 | 35/60/120 | 35/60/120 |

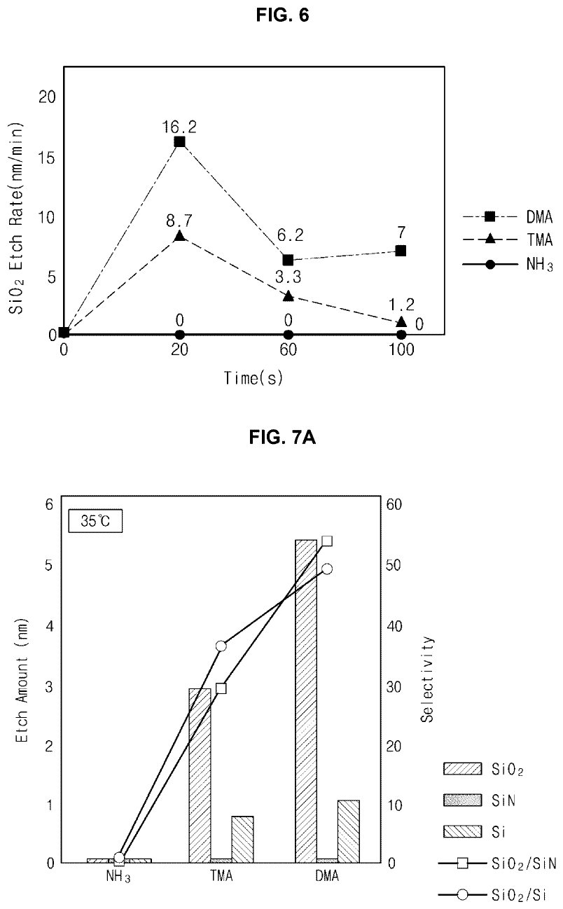

FIG. 6 is a graph illustrating the etch rate of a silicon oxide layer over time when the stage temperature is 35° C., and the internal pressure of the reactor is 3 torr.

Referring to FIG. 6, for ammonia, the silicon oxide layer was rarely etched regardless of time elapsed under the condition. On the contrary, for DMA and TMA, corresponding to the secondary amine and the tertiary amine, it may be recognized that the etching reaction was made at different degrees over time. For DMA and TMA, the highest etch rate was shown when 20 seconds were elapsed after the etching gas was supplied, and a lower etch rate was shown when 60 seconds were elapsed, as compared to when 20 seconds were elapsed. The reaction with the silicon oxide layer was increased for a specific time (for example, the time between about 10 seconds to about 30 seconds) after the etching gas was supplied, and then decreased after about 30 seconds were elapsed, which refers to that DMA and TMA self-limiting reaction with the surface of the silicon oxide layer.

In addition, it may be recognized that the etching reaction efficiency of the silicon oxide layer through DMA is significantly high, as the etch rate of the silicon oxide layer through DMA was shown as two times the etch rate of the silicon oxide layer through TMA.

### Experimental Example A-2: Etching Behavior of Silicon Oxide Layer Depending on Etching Target, Type of Etching Gas, and Temperature

After preparing a flat substrate having a layer, which is formed on a top surface thereof and serves as an etching target to be etched, an etch amount of the etching target depending on a temperature was determined by variously changing the type of the nitrogen-containing compound. The layer serving as the etching target was an SIO₂ layer, an SiN layer, an Si layer, an SiOCN layer, or an Si-enriched oxide (SRO) layer, and subject to the etching reaction at the temperature of 35° C., 60° C., or 120° C., respectively. In this case, the remaining conditions except for the etching target and the temperature were maintained to be the same as those in Experimental Example A-1.

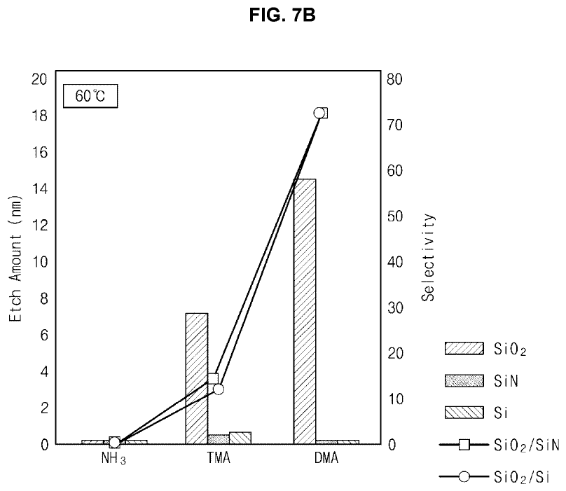

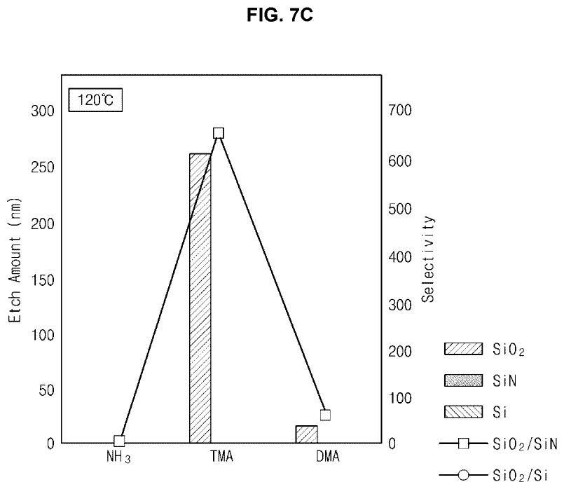

Table 2 shows results obtained by determining etch amounts of etching targets, and Table 3 shows etch selectivity for the etching targets. FIGS. 7A to 7C are graphs illustrating the etch amounts of the etching targets depending on the temperature, together with the selectivity of a specific etching target. The etch selectivity was shown as SiO₂/SiN or SiO₂/Si.

TABLE 2

| | Etch | | | |
|---|---|---|---|---|
| Temp | amount (nm) | NH₃ | TMA | DMA |
| 35° C. | SiO₂ | <0.1 | 2.9 | 5.4 |
| | SiN | <0.1 | <0.1 | <0.1 |
| | Si | <0.1 | 0.8 | 1.1 |
| | SiOCN | <0.1 | 0.5 | 0.7 |
| | SRO | <0.1 | 1.1 | 1.3 |
| 60° C. | SiO₂ | <0.1 | 7 | 14.4 |
| | SiN | <0.1 | 0.5 | 0.2 |
| | Si | <0.1 | 0.6 | 0.2 |
| 120° C. | SiO₂ | <0.1 | 262 | 15 |
| | SiN | <0.1 | 0.4 | 0.2 |
| | Si | <0.1 | 2.3 | 0.1 |

TABLE 3

| Temp | Etch amount (nm) | NH₃ | TMA | DMA |
|---|---|---|---|---|
| 35° C. | SiO₂/SIN | — | 29 | 54 |
| | SiO₂/Si | — | 4 | 5 |
| | SiO₂/SiOCN | | 5.8 | 7.7 |
| | SiO₂/SRO | — | 2.6 | 4.2 |
| 60° C. | SiO₂/SIN | — | 14 | 72 |
| | SiO₂/Si | — | 12 | 72 |
| 120° C. | SiO₂/SIN | — | 655 | 73 |
| | SiO₂/Si | — | 114 | 145 |

Referring to Table 2, Table 3, and FIGS. 7A to 7C, for ammonia, the reaction was hardly made with respect to all types of etching targets experimented. Accordingly, even an etch amount was small. Although not described in the above table, it may be recognized that even when ammonia is provided to the etching targets at a higher temperature (120° C.) and under higher pressure (9 Torr), an etching reaction is not observed, so the etching reaction was hardly made or slight.

DMA and TMA increased the etch amount of SiO₂ as the temperature is increased. In addition, TMA excessively increased the etch amount of SIO₂ when the temperature exceeds 100° C. In this case, the etch amount may not be adjusted to a desirable degree.

DMA showed an etch amount two times or at least two times greater than an etch amount for TMA with respect to the silicon oxide layer, at the temperature of 100° C. or less, for example, at the temperatures of 35° C. and 60° C. Even though DMA showed an etch amount at least two times greater than an etch amount for TMA with respect to the silicon oxide layer, DMA showed an etch amount equal to or less than an etch amount for TMA with respect to a different etching target (SiN or Si).

Regarding etch selectivity (SiO₂/SiN) of a silicon oxide layer over a silicon nitride layer, TMA and DMA showed the etch selectivity of 29 and the etch selectivity of 54 at a temperature of 35° C., respectively, and showed the etch selectivity of 14 and the etch selectivity of 72, at a temperature of 60° C., respectively. As described above, DMA showed the etch selectivity remarkably greater than the etch selectivity shown in TMA.

### Experimental Example A-3: Etching Behavior for Silicon Oxide Layer When Only Hydrogen Fluoride (HF) Is Employed as Etching Gas

After preparing a flat substrate having a layer, which is formed on a top surface thereof and serves as an etching target to be etched, an etch amount of the etching target depending on a temperature was determined by employing fluorinated gas as etching gas. The remaining conditions other than the etching gas were maintained to be the same as those in Experimental Example A-1.

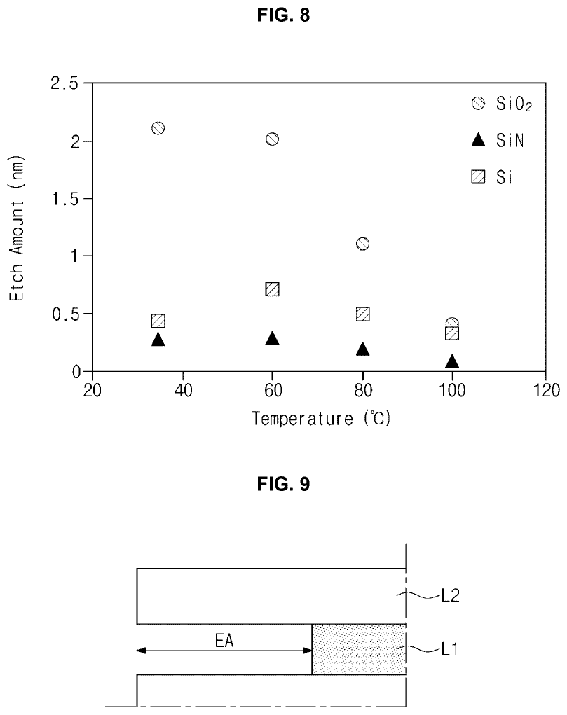

FIG. 8 is a graph illustrating an etch amount of an etching target as a function of a temperature when HF is employed as etching gas.

Referring to FIG. 8, when HF is employed as the etching gas, the silicon oxide layer, the silicon nitride layer, and silicon showed a lower etch rate, and a low etch selectivity (SiO₂/SiN). It was recognized that hydrogen fluoride in the gas phase is prevented from being adsorbed onto the surface, thereby reducing the etch rate of all layers, as the temperature is increased.

### EXPERIMENTAL EXAMPLE B: ETCHING BEHAVIOR IN STACK STRUCTURE

### Experimental Example B-1: Etching Behavior for Each Amine Compound in Stack Structure

After forming a stack structure by alternately stacking a silicon oxide layer and a silicon nitride layer, the etch amount of the silicon oxide layer was determined by employing the primary amine, the secondary amine, and the tertiary amine as the etching gas. Monomethylamine (MMA) was employed as the primary amine, dimethylamine (DMA) was employed as the secondary amine, and trimethylamine (TMA) and N,N-dimethylethylamine (N,N-DMEA) was employed as the tertiary amine.

In the present experiment, the flow rates of an amine compound, hydrogen fluoride, and argon were 40 standard cubic centimeters per minute (sccm), 40 sccm, and 35 sccm, respectively, the pressure of the reactor was 3 torr, and the stage temperature was 30° C. The reaction time was 20 seconds in each reaction, and five reactions were made. The time for the purging operation was at least 10 seconds in each reaction. In the present experiment, the stack structure was fabricated in the form illustrated in FIG. 9, the silicon oxide layer was provided at a first layer, L1 and the silicon nitride layer was provided at a second layer L2. The etch amount was measured based on a distance ‘EA’ from an end portion of the stack structure to the lateral side of the silicon oxide layer, which remains after the etching process, as illustrated in FIG. 9.

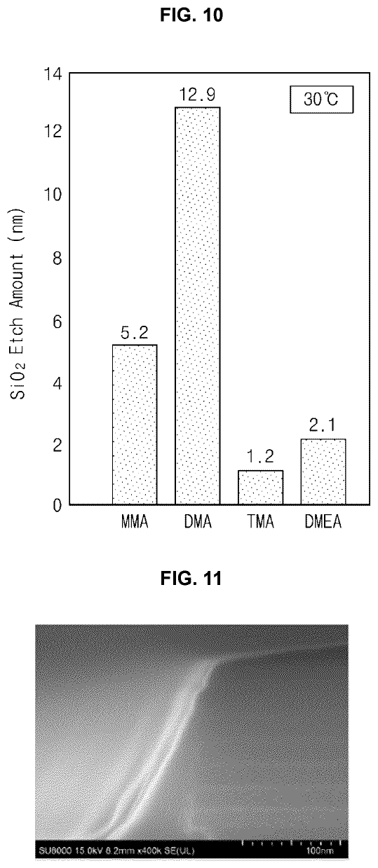

FIG. 10 is a graph illustrating an etch amount of each amine compound.

Referring to FIG. 10, the etch amount of at least 5 nm was shown, when the silicon oxide layer was etched using etching gas including MMA and DMA, while the etch amount of at most 3 nm was shown, when TMA and DMEA was used. Although not illustrated separately, when the silicon oxide layer was etched using the etching gas including MMA and DMA, the etch amount of the silicon nitride layer was less than 0.1 nm.

### Experimental Example B-2. Etching Behavior of Tertiary Amine Compound in Stack Structure

After forming a stack structure by alternately stacking a silicon oxide layer and a silicon nitride layer, the etch amount of the silicon oxide layer was determined by employing the tertiary amine (TMA) as the etching gas. In the present experiment, the flow rates of an amine compound, hydrogen fluoride, and argon were 40 sccm, 40 sccm, and 35 sccm, respectively, the pressure of the reactor was 3 torr, and the stage temperature was 30° C. The reaction time was 20 seconds in each reaction, and five reactions were made. In the present experiment, the stack structure was fabricated in the form illustrated in FIG. 3B, the silicon oxide layer was provided at a first layer L1, and the silicon nitride layer was provided at a second layer L2.

FIG. 11 is an SEM image illustrating the cross-section of the stack structure after the etching process is performed. As illustrated in FIG. 11, it may be recognized that the reaction by-product is piled on the sidewall of the stack structure, when the etching process is performed at the lower temperature of 30° C. using the etching gas including the TMA.

### Experimental Example B-3. Etching Behavior Depending on Pressure in Stack Structure

After forming a stack structure (the form illustrated in FIG. 3B) by alternately stacking a silicon oxide and a silicon nitride, the etch amount of the silicon oxide layer depending on pressure and critical dimension (CD) was determined by employing DMA and TMA as the etching gas. Each of the silicon nitride layers were formed at the thickness of 20 nm. In the present experiment, the reaction time was 20 seconds in each reaction, and five reactions were made as shown in Experimental Examples B-1 and B-2.

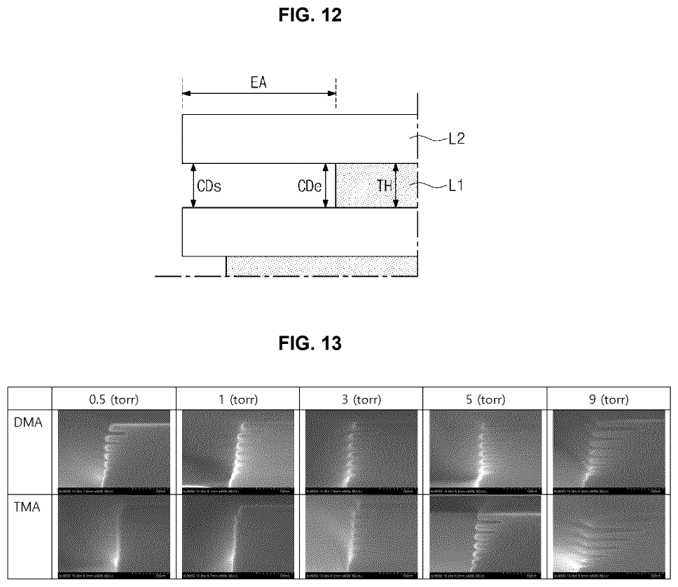

Table 4 is an example result illustrating an etch amount when the etching process is performed using DMA, and Table 5 is an example result illustrating an etch amount when the etching process is performed using TMA. Numeric values shown in Table 4 and Table 5 were measured with respect to a portion, which is illustrated in FIG. 12, of the stack structure. As illustrated in FIG. 12, the first layer L1 corresponds to the silicon oxide layer, and the second layer L2 corresponds to the silicon nitride layer. In this case, ‘TH’ indicates the stack thickness of the silicon oxide layer, ‘EA’ indicates an etch amount in a horizontal direction from a lateral side of the silicon oxide layer before etching the silicon oxide layer, ‘CDs’ indicates the thickness of the silicon oxide layer at the lateral side of the silicon oxide layer when the silicon oxide layer is etched, and ‘CDe’ indicates the thickness of the silicon oxide layer farthest away from the lateral side of the silicon oxide layer, when the silicon oxide layer is etched.

In the present experiment, all conditions were identically maintained, in addition to the internal pressure of the reactor and the type of the amine compound. In this case, the stack structure was fabricated in the form illustrated in FIG. 3B. The silicon oxide layer was provided at the first layer L1 and the silicon nitride layer were provided at the second layer L2. The thickness (TH) of the silicon oxide layer was formed to have a lower value in order.

TABLE 4

| | Pressure | | | | | | | | | | | | | | |
|---|---|---|---|---|---|---|---|---|---|---|---|---|---|---|---|
| | 0.5(Torr) | | | 1(Torr) | | | 3(Torr) | | | 5(Torr) | | | 9(Torr) | | |
| | Etch | | | Etch | | | Etch | | | Etch | | | Etch | | |
| | amount | | | amount | | | amount | | | amount | | | amount | | |
| Thickness | (nm) | | CDs- | (nm) | | CDs- | (nm) | | CDs- | (nm) | | CDs- | (nm) | | CDs- |
| of SiO₂ | SiO₂ | SiN | CDe | SiO₂ | SiN | CDe | SiO₂ | SiN | CDe | SiO₂ | SiN | CDe | SiO₂ | SiN | CDe |
| 10 nm | 60 | <1 | <1 | 75 | 1 | 4 | 80 | 1 | 6 | 100 | 5 | 5 | 140 | 6 | 3 |
| 7 nm | 40 | 2 | <1 | 50 | 2 | 3 | 60 | 3 | 2 | 70 | 4 | 5 | 100 | 7 | 4 |
| 5 nm | 35 | 2 | <1 | 40 | 2 | <1 | 50 | 3 | 1 | 50 | 3 | 1 | 95 | 6 | 5 |
| 4 nm | 30 | 3 | <1 | 30 | 2 | <1 | 45 | 2 | 1 | 50 | 4 | 1 | 90 | 5 | 5 |
| 3 nm | 10 | 2 | — | 20 | 2 | — | 30 | 3 | 3 | 35 | 5 | 2 | 70 | 6 | 2 |
| 2 nm | 0 | 2 | — | 10 | 2 | — | 15 | 4 | 1 | 20 | 6 | — | 30 | 5 | 1 |

TABLE 5

| | Pressure | | | | | | | | | | | | | | |
|---|---|---|---|---|---|---|---|---|---|---|---|---|---|---|---|
| | 0.5(Torr) | | | 1(Torr) | | | 3(Torr) | | | 5(Torr) | | | 9(Torr) | | |
| | Etch | | | Etch | | | Etch | | | Etch | | | Etch | | |
| | amount | | | amount | | | amount | | | amount | | | amount | | |
| Thickness | (nm) | | CDs- | (nm) | | CDs- | (nm) | | CDs- | (nm) | | CDs- | (nm) | | CDs- |
| of SiO₂ | SiO₂ | SiN | CDe | SiO₂ | SiN | CDe | SiO₂ | SiN | CDe | SiO₂ | SiN | CDe | SiO₂ | SiN | CDe |
| 10 nm | — | — | — | — | — | — | 55 | 1 | 2 | 75 | 4 | 5 | 190 | U.M.* | U.M. |
| 7 nm | — | — | — | — | — | — | 50 | 4 | 2 | 65 | 4 | 2 | 165 | 8 | 11 |
| 5 nm | — | — | — | — | — | — | 40 | 3 | 1 | 50 | 3 | 3 | 130 | 8 | 8 |
| 4 nm | — | — | — | — | — | — | 30 | 4 | 2 | 35 | 2 | 2 | 115 | 11 | 7 |
| 3 nm | — | — | — | — | — | — | 20 | 4 | <1 | 15 | 3 | <1 | 70 | 10 | 8 |
| 2 nm | — | — | — | — | — | — | 10 | 5 | — | 10 | 3 | — | 30 | 10 | 4 |

*U.M.: The measurement of etch amount is failed, as a layer collapsed due to over-etch is observed.

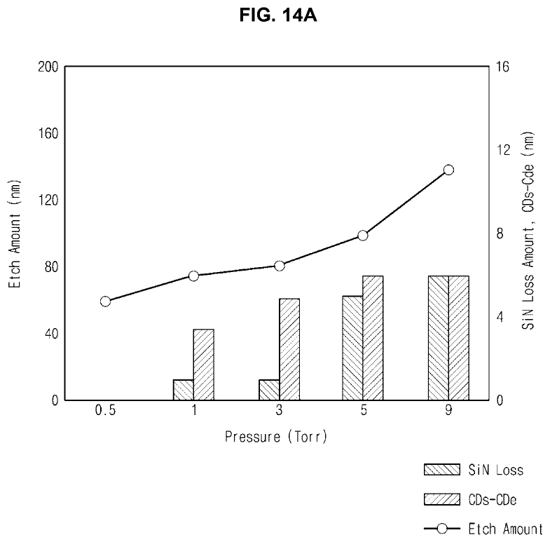

FIG. 13 is an SEM image illustrating an etch amount of the stack structure when the etching process is performed using dimethylamine and trimethylamine in Experimental Example B-3 and when the stack structure is viewed in a cross-sectional view.

Referring to Table 4, Table 5, and FIG. 12, when TMA, which is the tertiary amine compound, is included in etching gas, the etching reaction of the silicon oxide layer is hardly made at the lower pressure of 0.5 torr and 1 torr, so the measurement of the etch amount of the silicon oxide layer is failed. The etching reaction of the silicon oxide layer is made at the higher pressure of at least 3 torr. However, when only TMA is included in the etching gas, as the pressure is increased, even the silicon nitride layer is etched at a higher etch rate, so the silicon nitride layer collapse is observed.

On the contrary, when DMA, which is secondary amine compound, was included in the etching gas, the etching reaction of the silicon oxide layer was stably made even at the higher pressure as well as the lower pressure. In addition, the silicon nitride layer was etched in a significantly less amount, at both the lower pressure and the higher pressure. This result was interpreted as the selectivity of the silicon oxide layer over the silicon nitride layer is stable regardless of the pressure of the etching gas inside the reactor, when DMA is used as etching gas.

In addition, the value of CDs-CDe may be ‘0’ or may approximate to ‘0’, when the silicon oxide layer is etched inwardly, and when the silicon oxide layer is clearly etched with respect to the silicon nitride layer without reaction residues. The value of CDs-CDe may be increased, when the reaction residues remain or the silicon oxide layer is not fully etched. Referring to Table 4 and Table 5, dimethylamine shows the smaller value of CDs-CDe regardless of pressure as a whole, and trimethylamine shows the value CDs-CDe increased as pressure is increased. This indicates that the silicon oxide layer is not clearly etched or a great amount of residues remain when the reactor has greater pressure.

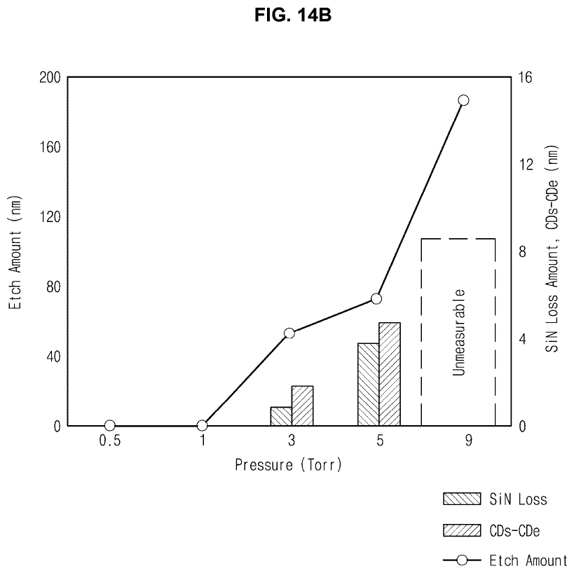

FIGS. 14A and 14B are graphs illustrating the etching behavior as a function of pressure, when the thickness of the silicon oxide layer is 10 nm. The graphs of FIGS. 14A and 14B illustrate data of Table 4 and Table 5. For TMA, it may be recognized that the detection of the etch amount is difficult due to the silicon nitride layer collapse, as the pressure is increased.

### Experimental Example B-4: Etch Selectivity Depending on Flow Rate Ratio of Secondary Amine Compound in Stack Structure

Regarding the flow rate of the etching gas supplied into the reactor, the flow rate of argon, which is inert gas, was fixed to 35 sccm, and the ratio in flow rate between DMA, which is the secondary amine compound, and hydrogen fluoride was variously changed while the etch amounts of the silicon oxide layer and the silicon nitride layer were determined. In the present embodiment, the remaining condition except for the ratio in flow rate between DMA and hydrogen fluoride was maintained to be the same as those in Experimental Example B-2.

Table 6 shows the etch amounts of the silicon oxide layer and the silicon nitride layer based on the ratio in flow rate between DMA and hydrogen fluoride.

TABLE 6

| Ratio in flow | Etch amount | Etch amount | Selectivity of |
|---|---|---|---|
| rate of HF:DMA | of SiO₂ (nm) | of SiN (nm) | SiO₂/SiN |
| 8:1 | 20 | 2 | 10 |
| 1:1 | 20 | — | ∞ |
| 1:10 | 20 | — | ∞ |
| 1:50 | <1 | — | — |

Referring to Table. 6, when the ratio in flow rate between hydrogen fluoride and DMA is 8:1, the selectivity reaches 10. When the ratio in flow rate between hydrogen fluoride and DMA is 1:1 or 1:10, the silicon nitride layer is hardly etched, so the etch selectivity of the silicon oxide layer is significantly higher. However, it may be recognized that etching failed as the reaction is difficult due to hydrogen fluoride when the ratio in flow rate between hydrogen fluoride and DMA is 1:50.

### Experimental Example B-5: Etching Behavior Depending on Amine Compound and Etching Reaction Time in Stack Structure

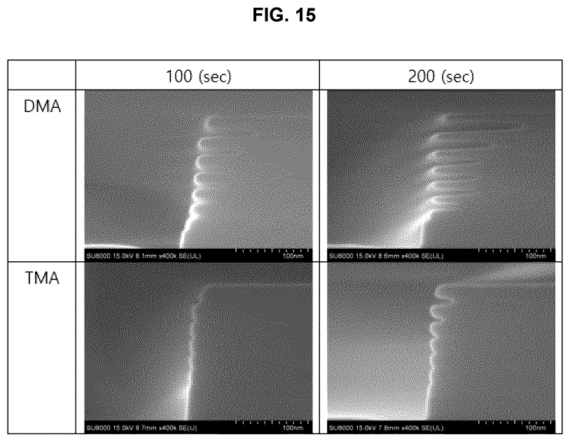

The etch amount of the silicon oxide layer was determined by variously changing the etching reaction time, when the silicon oxide layer is etched using etching gas including DMA, which is the secondary amine compound, and TMA which is the tertiary amine compound. Table 7 shows the etching results for the etching reaction times of 100 seconds and 200 seconds with respect to etching gas including DMA and etching gas including TMA, when the flow rates of an amine compound, hydrogen fluoride, and argon were 40 sccm, 40 sccm, and 35 sccm, respectively, the reaction pressure was 1 torr, and a stage temperature was 60° C. FIG. 15 illustrates SEM images of cross-sections of etching results depending on reaction times and amine compounds.

TABLE 7

| | Time (sec) | | | | | | | | | | | |
|---|---|---|---|---|---|---|---|---|---|---|---|---|
| | DMA | | | | | | TMA | | | | | |
| | 100 | | | 200 | | | 100 | | | 200 | | |
| | Etch amount | | | Etch amount | | | Etch amount | | | Etch amount | | |
| Thickness | (nm) | | CDs- | (nm) | | CDs- | (nm) | | CDs- | (nm) | | CDs- |
| of SiO₂ | SiO₂ | SiN | Cde | SiO₂ | SiN | Cde | SiO₂ | SiN | Cde | SiO₂ | SiN | Cde |
| 10 nm | 75 | 1 | 4 | 120 | 8 | 6 | N.D | N.D | N.D | 25 | 3 | 3 |
| 7 nm | 50 | 2 | 3 | 80 | 8 | 4 | N.D | N.D | N.D | 15 | 3 | N.D |
| 5 nm | 40 | 2 | <1 | 60 | 7 | 4 | N.D | N.D | N.D | 10 | N.D | N.D |
| 4 nm | 30 | 2 | 1 | 60 | 6 | 4 | N.D | N.D | N.D | N.D | N.D | N.D |
| 3 nm | 20 | 2 | N.D. | 60 | 7 | <1 | N.D | N.D | N.D | N.D | N.D | N.D |
| 2 nm | 10 | 2 | N.D | 30 | 9 | 2 | N.D | N.D | N.D | N.D | N.D | N.D |

Referring to Table 7 and FIG. 15, for etching gas including TMA, which is the tertiary amine compound, it may be recognized that the etching is hardly made regardless of the etching reaction time, under the lower pressure of 1 torr.

The present disclosure provides the method for dry-etching the silicon oxide layer, capable of selectively etching a fine silicon oxide pattern.

According to the method for dry-etching the silicon oxide layer according to the present disclosure, the silicon oxide layer may be selectively etched even at the lower temperature of 100° C. or less without residue resulting from the etching reaction.

Although embodiments of the present disclosure have been described, those skilled in the art will understand that various modifications, and variations are possible, without departing from the scope and spirit of the present disclosure as disclosed in the accompanying claims.

Accordingly, the technical scope of the present disclosure is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method for dry-etching a silicon oxide layer, the method comprising:
allowing etching gas including hydrogen fluoride, an amine compound, and inert gas to react with a stack structure, the stack structure including a first layer comprising the silicon oxide layer and a second layer comprising a material different from the silicon oxide layer, the second layer being stacked on the first layer, thereby selectively-etching the silicon oxide layer,
wherein the selective-etching of the silicon oxide layer includes:
allowing the etching gas to react in a self-limiting reaction with an exposed region at the first layer; and
removing the region subject to the self-limiting reaction, and wherein the amine compound includes at least one compound of Chemical Formula 1, 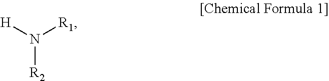
in which each of R₁ and R₂ is independently hydrogen or a substituted or unsubstituted aliphatic or aromatic hydrocarbon group having 1 to 12 carbon atoms and R₁ and R₂ are not simultaneously hydrogen, wherein the substituted aliphatic or aromatic hydrocarbon group is substituted with nitrogen, oxygen, sulfur, phosphorus, and/or halogen atoms.

2. The method of claim 1, wherein the selective-etching of the silicon oxide layer is performed multiple times.

3. The method of claim 2, wherein both a reaction product produced after the self-limiting reaction and remaining etching gas are purged in one cycle.

4. The method of claim 1, wherein the second layer includes one of a silicon nitride layer, a silicon layer, and a SiOCN layer.

5. The method of claim 4, wherein the second layer is a silicon nitride layer.

6. The method of claim 1, wherein the selective-etching of the silicon oxide layer is performed at a temperature ranging from −50° C. to 150° C.

7. The method of claim 6, wherein the etching gas is supplied to the exposed region of the silicon oxide layer for a time ranging from 10 seconds to 30 seconds.

8. The method of claim 7, wherein the etching gas is supplied into a reactor which has a target substrate received in the reactor and having the silicon oxide layer, and wherein pressure of the etching gas in the reactor ranges from 0.001 torr to 10 torr.

9. The method of claim 1, wherein a ratio in flow rate between the hydrogen fluoride and the amine compound ranges from 0.05:1 to 1:30 hydrogen fluoride: amine compound.

10. The method of claim 1, wherein the amine compound is at least one of methylamine, dimethylamine, methyl-ethylamine, ethylamine, diethylamine, propylamine, dipropylamine, butylamine, dibutylamine, tertiary butylamine, di-tert-butylamine, pyrrolidine, piperidine, piperazine, pyridine, or pyrazine.

11. The method of claim 10, wherein the amine compound is at least one of dimethylamine, diethylamine, di-n-propylamine, diisopropylamine, dibutylamine, or di-tert-butylamine.

12. The method of claim 1, wherein the amine compound and the hydrogen fluoride of the etching gas are sequentially supplied to the stack structure.

13. The method of claim 1, wherein the hydrogen fluoride and the amine compound are first mixed with each other, and then supplied to the stack structure.

14. The method of claim 1, wherein the first layer and the second layer include, respectively, a plurality of first layers and a plurality of second layers which are alternately stacked on each other.

15. The method of claim 1, further comprising:
a third layer provided on at least one layer of the first layer or the second layer and including a material different from a material of the first layer and a material of the second layer.

16. A method for dry-etching a silicon oxide layer, the method comprising:
performing a dry-etching process for removing the silicon oxide layer by allowing etching gas including hydrogen fluoride, an amine compound of Chemical Formula 1, and inert gas to react with the silicon oxide layer,
wherein the performing of the dry-etching process includes:
allowing the etching gas to react in a self-limiting reaction with an exposed region of the silicon oxide layer; and
removing the region subject to the self-limiting reaction, 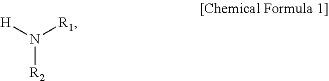
in which each of R₁ and R₂ is independently hydrogen or a substituted or unsubstituted aliphatic or aromatic hydrocarbon group having 1 to 12 carbon atoms and R₁ and R₂ are not simultaneously hydrogen, wherein the substituted aliphatic or aromatic hydrocarbon group is substituted with nitrogen, oxygen, sulfur, phosphorus, and/or halogen atoms.

17. The method of claim 16, wherein the dry-etching step is performed at a temperature ranging from −50° C. to 150° C., and
wherein the etching gas is supplied to an exposed region of the silicon oxide layer for a time ranging from 10 seconds to 30 seconds.

18. The method of claim 17, wherein the etching gas is supplied in a ratio in flow rate between the hydrogen fluoride and the amine compound from 0.05:1 to 1:30 hydrogen fluoride: amine compound.

19. A method for fabricating a semiconductor device, the method comprising:
selectively dry-etching a silicon oxide layer by allowing etching gas including hydrogen fluoride, an amine compound of Chemical Formula 1, and inert gas to react with a semiconductor substrate having a stack structure in which silicon oxide layers and silicon nitride layers are alternately stacked on each other in a first direction,
wherein the selectively dry-etching of the silicon oxide layer includes:
allowing the etching gas to react in a self-limiting reaction with an exposed region of the silicon oxide layer; and
removing a region subject to the self-limiting reaction, 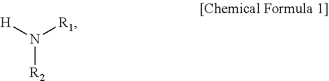
wherein each of R₁ and R₂ is independently hydrogen or a substituted or unsubstituted aliphatic or aromatic hydrocarbon group having 1 to 12 carbon atoms and R₁ and R₂ are not simultaneously hydrogen, and the substituted aliphatic or aromatic hydrocarbon group is substituted with nitrogen, oxygen, sulfur, phosphorus, and/or halogen atoms.

20. The method of claim 19, wherein the selectively dry-etching step is performed at a temperature ranging from −50° C. to 100° C.,
wherein the etching gas is supplied to an exposed region of the silicon oxide layer for a time ranging from 10 seconds to 30 seconds, and
wherein a ratio in flow rate between the hydrogen fluoride and the amine compound ranges from 0.05:1 to 1:30 hydrogen fluoride: amine compound.
